(19) United States
(12) Patent Application Publication
(10) Pub. No.: US 2008/0311426 A1
(43) Pub. Date: Dec. 18, 2008

(54) Organic EL Display and Method for Manufacturing the Same

(75) Inventor: Eiichi Kitazume, Tokyo (JP)

Correspondence Address: SQUIRE, SANDERS & DEMPSEY L.L.P., 1 MARITIME PLAZA, SUITE 300, SAN FRANCISCO, CA, 94111, US

(73) Assignee: Toppan Printing Co., Ltd., Tokyo (JP)

(21) Appl. No.: 12/139,395

(22) Filed: Jun. 13, 2008

(30) Foreign Application Priority Data
Jun. 18, 2007 (JP) 2007-159859

(51) Int. Cl. C09K 11/00; B05D 5/06

(52) U.S. Cl. 428/690; 427/64

(57) ABSTRACT

One embodiment of the present invention is an organic EL display, including a transparent substrate, a plurality of pixel electrodes formed on the transparent substrate, a plurality of insulating medium layers of 100 nm thickness or more sectioning the plurality of pixel electrodes, a plurality of hole transport layers formed on the plurality of pixel electrodes, a plurality of organic light emitting layers formed on the plurality of hole transport layers, an angle between a side surface of an insulating medium layer and a surface of a hole transport layer or an organic light emitting layer being 30 degrees or less, and a counter electrode formed on the plurality of organic light emitting layers.

### CROSS REFERENCE

This application claims priority to Japanese application number 2007-159859, filed on Jun. 18, 2007, which is incorporated herein by reference.

### BACKGROUND OF THE INVENTION

1. Field of the Invention

The present invention is related to an organic EL (electroluminescence) display and a method for manufacturing the organic EL display. Especially, the present invention is related to an organic EL display and a method for manufacturing the organic EL display in which the display is manufactured by a wet process.

2. Description of the Related Art

An organic EL device has an organic light emitting layer comprising organic light emitting material between two opposing electrodes. By means of applying electric current to the organic light emitting layer between both electrodes, the organic light emitting layer emits light. Thickness of the organic light emitting layer is important so that the organic luminous layer emits light efficiently and reliably.

In the case of manufacturing a color-display using this organic EL device, it is necessary to perform patterning of the organic EL device with high definition.

As the organic light emitting material for forming the light emitting layer, a low molecular material and a polymer material are usable. The low molecular material is subjected to vacuum vapor deposition and the like to form a thin film, and at the same time the patterning is performed by using a microscopically patterned mask. However, this method has a problem that patterning accuracy is reduced with an increase in size of a substrate. In addition, there is a problem in which throughput is bad due to depositing in vacuum.

Thus the following method is tried recently: polymer material is dissolved in a solvent; thereby, ink is made; and a thin film is formed by a wet coating method using this ink.

A layer structure of an organic light emitting medium layer when an organic light emitting medium layer including an organic light emitting layer is formed by wet coating using coating solution of high polymer materials is described below. A two-layer structure in which a hole transport layer and an organic light emitting layer are deposited on an anode in this order is generally used. As for the organic light emitting layer, it is necessary for the organic light emitting inks respectively including organic light emitting materials of red (R) green (G) and blue (B) in solvents to be separately applied in order to form a color panel.

FIG. 5 is an explanatory cross-sectional organic EL display panel of a conventional type. A hole transport layer 2 and an organic light emitting layer 1 are formed on a pixel electrode 3. Conventionally, it is tried that a display quality is improved by making these two layers uniform. However, in this case, if a counter electrode 6 is formed based on a cross-sectional shape of an insulating medium layer 5, a counter electrode 6 at a border part of an organic light emitting layer and an insulating medium layer 5 becomes thin due to a shielding effect of an insulating medium layer 5 and a counter electrode itself during deposition. This causes a disconnection or a locally high resistance. Therefore, a method for making a counter electrode thick has been studied in order to prevent such a phenomenon. However, there is a problem in which it takes long time for forming a thick film, thereby a takt time becomes long.

As a film formation method using a wet process, an offset printing method (See patent document 1) using a rubber blanket having an elasticity, a relief printing method (See patent document 2) using a rubber printing plate or a resin printing plate having an elasticity and an ink jet method (See patent document 3) are proposed. In addition, for example, structure of an organic EL display is disclosed. The organic EL display has at least one organic layer having a concave cross-sectional structure near a rib. It is not necessary that an organic layer has a concave structure before an electrode is formed. In the case where an organic layer has a convex structure, if an electrode is formed thereon, a disconnection of an electrode occurs or resistance of an electrode becomes high due to a locally thinned film (electrode film). The high resistance of an electrode causes a disconnection of an electrode. (See patent document 4)

In the above-mentioned coating method, a defect of a pixel should be prevented, the defect caused by an uneven luminance or an electric field concentration due to an uneven film thickness of an organic light emitting layer inside a pixel. Therefore, it is necessary that a film thickness inside a pixel should be even by controlling a viscosity of an ink or surface tensions of an ink, a substrate and an insulating medium sectioning a pixel. Further, it is necessary that an ink is prevented from flowing to an adjacent pixel. It was found that an insulating medium having a contact angle of 30 degrees or more should be formed by CF₄ plasma processing. A surface tension of an insulating medium sectioning a pixel is increased by CF₄ plasma processing. Thereby, an insulating medium has an ink-repellent property.

Further, it was found that a failure of displaying may occur depending on a shape of an insulating medium layer sectioning a pixel. That is, if a film thickness of an organic light emitting layer inside a pixel is uniform, an electrode formed thereon is broken or is locally thinned due to a precipitous cross-section of an insulating medium sectioning a pixel and a shielding effect, resistance of the thinned electrode increasing. Therefore, a disconnection of an electrode is prevented by thickening a film thickness of an electrode. However, it is necessary that a film thickness of an electrode should be more than a necessary thickness. Thereby, takt in film formation is increased. So, mass productivity becomes low. In addition, it was found that a locally uneven light emitting inside a pixel does not badly influence a display from a macroscopic view.

Then, the objective of the present invention is to provide an organic EL display in which a disconnection or a locally high resistant part of a counter electrode formed on an organic layer is prevented. That is, in an organic EL display, a distance between a surface of a pixel electrode and a most outer surface of layers except for a counter electrode increases from a part directly above a border between a side surface of an insulating medium layer and a surface of a pixel electrode to an insulating medium layer. In this structure, an organic EL display is provided in which a disconnection or a locally high resistant part of a counter electrode formed on an organic layer is prevented. The counter electrode is formed by a shielding effect due to an edge shape of an insulating medium layer or an organic light emitting layer.

[patent document 1] JP-A-2001-93668

[patent document 2] JP-A-2001-155858

[patent document 3] JP-A-2002-305077

[patent document 4] JP-A-2001-76881

### SUMMARY OF THE INVENTION

One embodiment of the present invention is an organic EL display, including a transparent substrate, a plurality of pixel electrodes formed on the transparent substrate, a plurality of insulating medium layers of 100 nm thickness or more sectioning the plurality of pixel electrodes, a plurality of hole transport layers formed on the plurality of pixel electrodes, a plurality of organic light emitting layers formed on the plurality of hole transport layers, an angle between a side surface of the insulating medium layer and a surface of the hole transport layer or the organic light emitting layer being 30 degrees or less, and a counter electrode formed on the plurality of light emitting layers.

Another embodiment of the present invention is a method for manufacturing an organic EL display including a pixel electrode, a counter electrode, a hole transport layer and an organic light emitting layer, the method including forming a plurality of pixel electrodes on a transparent substrate, forming a plurality of insulating medium layers having a height of 100 nm or more over than surfaces of the plurality of pixel electrode, the layers sectioning the pixel electrodes, and forming the hole transport layer or the organic light emitting layer by a wet process using a thin film material solution, a contact angle between a side surface of the insulating medium layer and the thin film material solution being 30 degrees or less.

### BRIEF DESCRIPTION OF THE DRAWINGS

FIG. 1 is an explanatory cross-sectional diagram of one embodiment of an organic EL device in the present invention.

FIG. 2 is an explanatory enlarged cross-sectional diagram of one embodiment of an organic EL device in the present invention.

FIG. 3 is an explanatory enlarged cross-sectional diagram of one embodiment of an organic EL device in the present invention.

FIG. 4 is a schematic diagram of a relief printing apparatus.

FIG. 5 is an explanatory enlarged cross-sectional diagram of a conventional organic EL device.

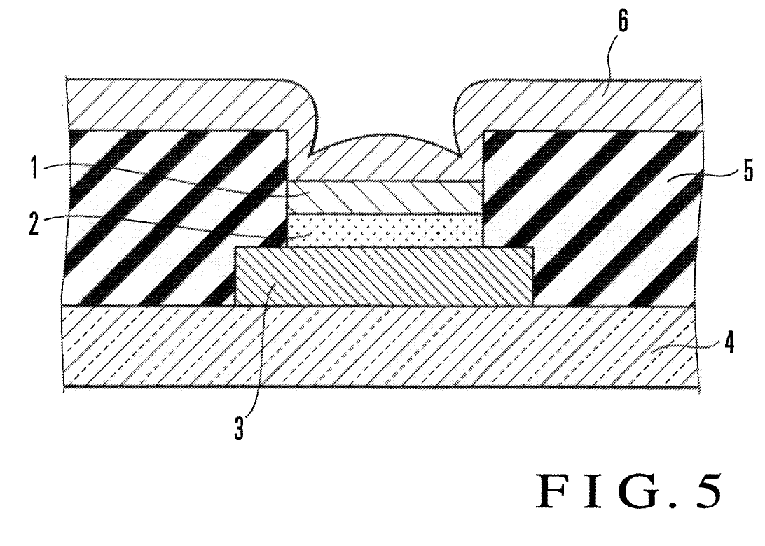

FIG. 6 is an explanatory enlarged cross-sectional diagram of one embodiment of an organic EL device in the present invention.

In these drawings, 1 is an organic light emitting layer; 2 is a hole transport layer; 3 is a pixel electrode; 4 is a transparent substrate; 5 is an insulating medium layer; 6 is a counter electrode; 7 is a glass cap; 8 is an adhesive; 10 is an ink tank; 11 is an ink chamber; 12 is an anilox roll; 12a is an ink layer; 13 is a printing plate; 14 is a plate cylinder; 15 is a substrate (a substrate to be printed); 16 is a flat base; and 100 is an organic EL device.

### DETAILED DESCRIPTION OF THE INVENTION

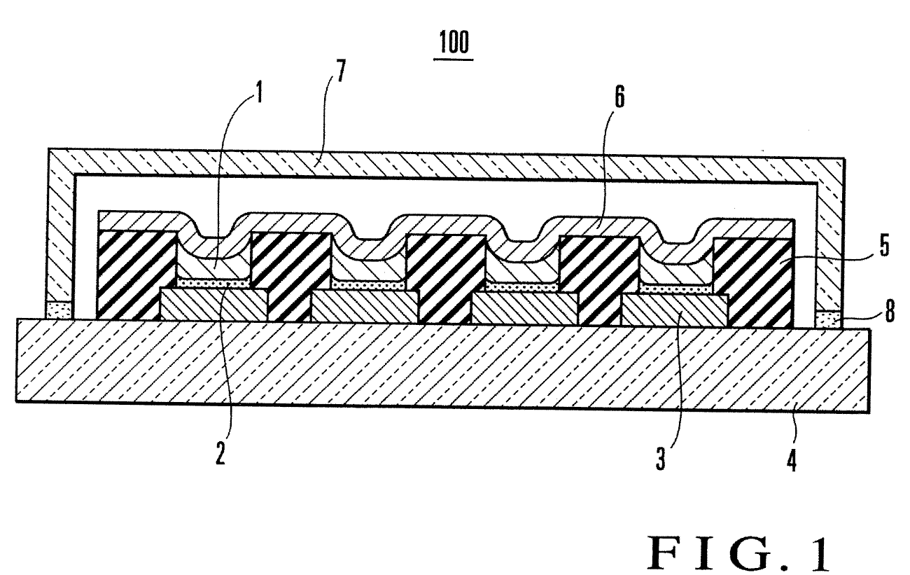

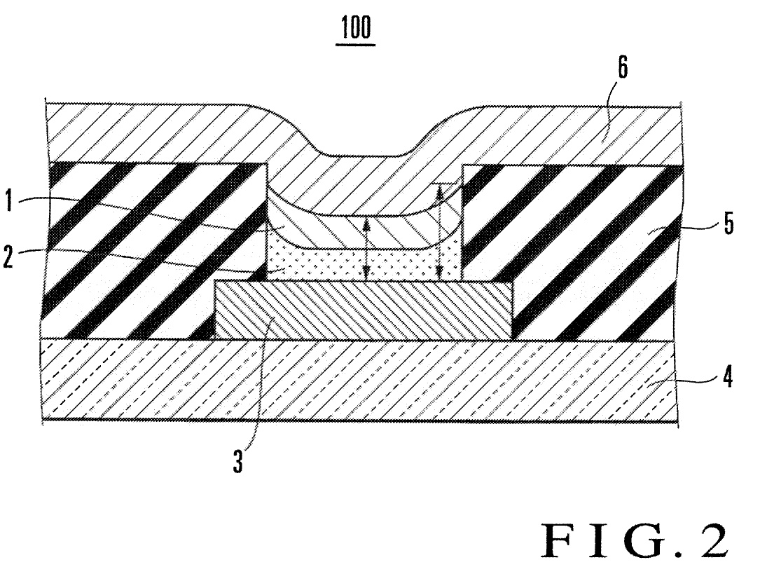

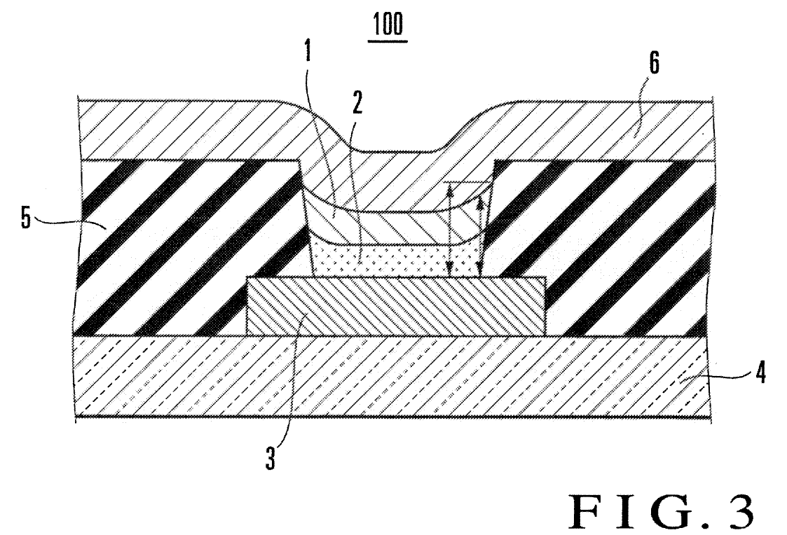

As shown FIG. 1, an organic EL device 100 of an embodiment of the present invention is arranged at an intersection of pixel electrode 3 and a counter electrode 6, pixel electrode extending in a first direction and a counter electrode 6 extending in a second direction, and both electrode being not illustrated. An organic EL device has a transparent substrate 4, a pixel electrode 3, an insulating medium layer, a hole transport layer 2, an organic light emitting layer 1 and a counter electrode. In this embodiment of the present invention, a case is described in which a passive matrix type display is manufactured. However, the present invention is not limited to this. In addition, FIG. 2 is an enlarged cross-sectional figure of FIG. 1. Further, FIG. 3 is an enlarged cross-sectional figure in the case where the side surface of the insulating medium layers slope. A distance between an upper surface of a pixel electrode and an upper surface of a light emitting layer at an about center position of a pixel is longer than that at a position near an insulating medium layer. This relationship is shown by arrows in FIGS. 2 and 3.

An organic EL device 100 in an organic EL display is formed on transparent substrate 4. For a transparent substrate 4, a glass substrate and a plastic film or sheet can be used. If a plastic film is used, a polymer type EL device can be manufactured by winding-up. In other words an inexpensive display panel can be manufactured. In addition, for the plastic, polyethylene terephthalate, polypropylene, cyclo-olefin polymers, polyamide, polyethersulfone, polymethyl methacrylate and polycarbonate can be used. However, usable plastics are not limited to these. In addition, a steam or oxygen barrier layer comprising a metallic oxide such as silicon oxide, oxynitrides such as silicon nitrides and polyvinylidene chloride, polyvinyl chloride, saponified ethylene-vinyl acetate copolymer can be formed on these films if necessary.

In addition, non-transparent substrate can be used if necessary.

Pattern-formed pixel electrodes 3 are formed on a transparent substrate 4 as anodes. For the materials of pixel electrodes 3, transparent electrode materials such as ITO (indium tin complex oxide), IZO (indium zinc complex oxide), tin oxide, zinc oxide, indium oxide and zinc aluminium complex oxide can be used.

In addition, the electrical resistance of ITO is low. ITO has a solvent resistance, and is transparent. Therefore, ITO is preferable. ITO is formed on a transparent substrate 4 by sputter method etc. Patterning of ITO is performed by a photolithography method. ITO becomes line-shaped pixel electrodes 3 in this way.

After a line-shaped pixel electrode 3 has been formed, an insulating medium layer 5 is formed between adjacent pixel electrodes 3. Any one of an inorganic nitride film, an inorganic oxide film and an inorganic fluoride can be used for a material of an insulating medium layer 5. However, usable materials are not limited to these. If an oxide, an nitride and an fluoride of which surface tension is higher than that of a resist generally used for an insulating medium layer 5 is used, affinity of an ink is improved. Therefore, a smooth taper is formed at an edge part of an insulating medium layer 5. So, a defect of an electrode formed thereon can be prevented. In the case where an insulating medium layer 5 is formed, silicon oxide can be used. Silicon oxide is deposited by a reactive sputtering method. Thereafter, pattern of silicon oxide is exposed by using a photo resist. Then, a pattern of silicon oxide is formed by a reactive etching.

After forming insulating medium layer 5, hole transport layer 2 is formed. Examples of hole transport materials which forms hole transport layer 2 include poly aniline derivative, poly thiophenes, polyvinylcarbazole (PVK) derivative and poly(3,4-ethylenedioxy thiophene) (PEDOT). These materials are dissolved or dispersed in a solvent and hole transport layer 2 is formed by various application methods using a spin coater or the like, or a relief printing method.

After forming hole transport layer 2, an organic light emitting layer 1 is formed. An organic light emitting layer 1 is a layer emitting light by an electric current. Examples of organic light emitting materials forming organic light emitting layers 1 include the materials which are light emitting pigments such as coumarin system, perylene system, pyran system, anthrone system, porphyrin system, quinacridon system, N,N′-dialkyl permutation quinacridon system, naphthalimido system, N,N′-diaryl permutation pyrrolo pyrrole series and iridium complex system. These materials can be scattered in macromolecules such as polystyrene, polymethyl methacrylate and polyvinyl carbazole. In addition, high polymer materials such as poly arylene system, PAV [polyarylenevinylene] system, a poly fluorene system or a polyphenylene vinylene system can be used. However, usable organic light emitting materials are not limited to these.

An organic light emitting ink is prepared by dissolving or stably dispersing these organic light emitting materials in a solvent.

For a solvent dissolving or dispersing an organic light emitting material, toluene, xylene, acetone, anisole, methyl ethyl ketone, methyl isobutyl ketone and cyclohexanone can be used. The above-mentioned solvent may be used alone. In addition, the above mentioned solvent may be used as a mixed solvent.

Above all, aromatic organic solvent such as toluene, xylene and anisole is preferred from an aspect of solubility of an organic light emitting material.

In addition, detergent, antioxidant, viscosity modifier, UV absorber or the like may be added in an organic light emitting ink as needed.

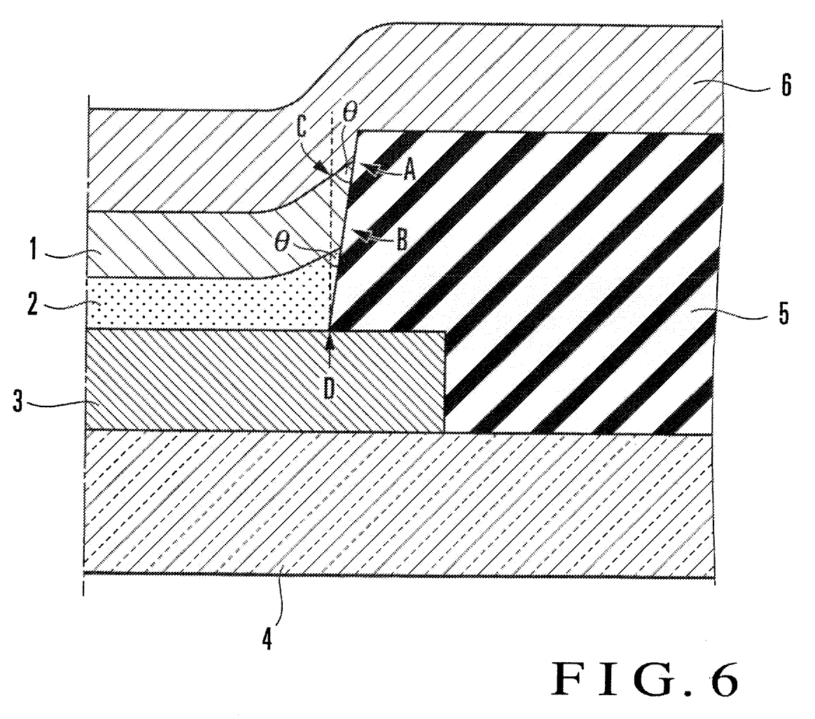

Further, it is desirable that an angle between a side surface of an insulating medium layer 5 and a surface of a hole transport layer 2 or an organic light emitting layer 1 be equal to or less than 30 degrees. Here, as shown in FIG. 6, an angle between a side surface of an insulating medium layer 5 and a surface of a hole transport layer 2 or an organic light emitting layer 1 is an angle θ. As illustrated by FIG. 6, angle θ is between a side surface of an insulating medium layer 5 and a surface between a part of a hole transport layer 2 or an organic light emitting layer, being contact with the insulating medium layer 5 and a part of the surface of a hole transport layer 2 or an organic light emitting layer, directly above a border between a side surface of an insulating medium layer and a pixel electrode. In FIG. 6, a position (A) is a part of an organic light emitting layer, being contact with the insulating medium layer 5. Further, a surface (B) is a side surface of an insulating medium layer 5. Position (C) is a part of the surface of an organic light emitting layer, directly above a border between a side surface of an insulating medium layer and a pixel electrode. Position (D) is a border between a side surface of an insulating medium layer and a pixel electrode.

After having formed organic light emitting layer 1, a line pattern counter electrode layer 6 which is perpendicular to line pattern pixel electrodes is formed. For a material of a counter electrode layer 6, the material which is suitable for light emitting property of an organic light emitting layer can be used. For example, a metal simple substance such as lithium, magnesium, calcium, ytterbium and aluminium can be used. An alloy of the above mentioned metal simple substance and the stable metal such as gold and silver can be used. In addition, conductive oxidate of indium, zinc, tin or the like can be used. For formation method of a counter electrode 6 (a cathode layer), a vacuum vapor deposition method using a mask or a sputter method can be used. In addition, before forming a counter electrode 6, a barrier layer etc. can be formed if necessary.

In addition, a hole transport layer 2, a hole injection layer and an electronic blocking layer are layers having material having hole transport characteristics and/or electron block characteristics. Such layers have the following roles, respectively: such a layer reduces a barrier of hole injection from an anode layer to an organic light emitting layer; such a layer sends a hole poured from an anode layer toward a cathode layer; and such a layer disturbs that an electron advances toward an anode layer while keeping a hole passing. A hole blocking layer and an electron transport layer are layers having materials having electron transport property and/or hole block characteristics. Such layers have the following roles, respectively: such a layer makes a poured electron advance from a cathode layer toward an anodal layer; and such a layer disturbs the situation that a hole goes toward a cathode layer while keeping electron passing.

Finally, the organic EL device is sealed using a glass cap 7 and an adhesive 8 in order to protect the organic EL device from outside oxygen and moisture. An organic EL display panel can be obtained in this way.

In addition, in the case where a transparent substrate 4 is a flexible transparent substrate, the organic EL device is sealed using a sealing material and a flexible film.

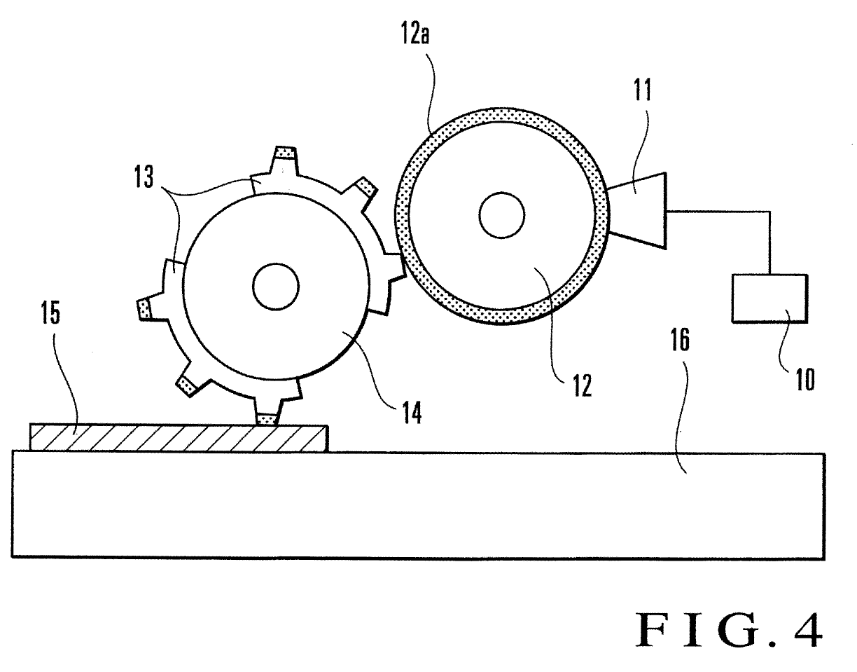

FIG. 4 shows a schematic diagram of a relief printing apparatus which pattern-prints an organic light emitting ink comprising an organic light emitting material on a substrate on which pixel electrodes 5, an insulating medium layer 5 and a hole transport layer 2 are formed.

This relief printing device has an ink tank 10, an ink chamber 11, an anilox roll 12 and a plate cylinder 14 on which a plastic relief printing plate 13 is equipped. An organic light emitting ink which is diluted with a solvent is taken to an ink tank 10. An organic light emitting ink is sent into an ink chamber 11 from an ink tank 10. An anilox roll 12 makes contact with an ink feed section of an ink chamber 11, and it is rotatably supported.

According to rotation of an anilox roll 12, ink layer 12a comprised of an organic light emitting ink supplied on an anilox roll face becomes uniform. This ink layer transfers on projection parts of a plate 13 mounted on a printing cylinder 14 which is rotationally driven in proximity to an anilox roll. A substrate 15 on which transparent electrodes and an insulator layer are formed is transported to a printing position of a flat base 27 by the transporting means that are not illustrated. And ink on projection parts of a plate 13 is printed on a substrate 15. And ink is dried if necessary. An organic light emitting layer 1 is formed on a substrate in this way.

In the case of a relief printing method, when a convex part of a relief printing plate pushes an underlayer, an ink is protruded to both sides. The protrusion called a marginal zone. Further, the protrusion makes a smooth taper at an edge part of an insulating medium layer 5. Thereby, defect of an electrode formed thereon can be prevented.

According to the present invention, an organic EL display can be provided in which breaking of a counter electrode or occurring of a local high resistance part in a counter electrode is prevented, wherein the counter electrode is formed on an organic light emitting layer.

An insulating medium layer has a height of 100 nm over than a pixel electrode surface in order to section a pixel.

A distance between a surface of a pixel electrode and a surface of an organic light emitting layer increases from a point immediately above a border between a side part of an insulating medium layer and a pixel electrode to an insulating medium layer. Thereby, a non-uniform film is willfully formed inside a pixel. A sheer side surface of an insulating medium layer becomes a taper surface because of an organic light emitting layer. Thereby, a counter electrode formed thereon has an almost uniform film thickness. So, breaking of a counter electrode or increasing of resistance of a counter electrode, which caused by a local thinned part of a counter electrode, can be prevented. Therefore, an organic EL display without a display failure can be obtained.

Usually, as an electrode, a conductive film having a thickness of about 100 nm or more is formed in view of a resistance of a wiring.

### EXAMPLE 1

ITO thin film was formed by sputter method on a glass substrate 4 of which diagonal was 1.8 inches. Patterning of ITO thin film was performed by photolithography method and etching using an acid solution. Pixel electrodes 3 were formed in this way.

Line pattern of pixel electrodes 3 is described below. Line width was 136 μm. Space width was 30 μm. There were 192 lines on a glass substrate of 32 mm square.

Next, an insulating medium layer 5 was formed by processes described below. A silicon oxide film of 40 nm thickness was deposited on a glass substrate 4 with a pixel electrode 3 by RF magnetron sputtering method. Film deposition (film formation) was performed under conditions described below by a reactive sputtering method. Degree of vacuum in the film formation was 3.8×10⁻⁴ Torr. Flow rate of introduced Ar gas was 17 sccm. Flow rate of introduced oxygen gas was 5 sccm. Electric discharge was 0.2 kW.

Thereafter, patterning of the silicon oxide film was performed by a reactive etching after a pattern was exposed using a photo resist. Here, CF₄ was used as an etching gas.

Here, an angle between the insulating medium layer 5 and the pixel electrode 5 was 76 degrees. That is, the insulating medium layer 5 had a taper shape.

Next, a substrate 1 with pixel electrode 3 and the insulating medium layer 5 was processed by oxygen plasma for 2 minutes. The conditions of the oxygen plasma processing are described below. Flow rate of oxygen gas was 500 sccm. Power was 1.0 W/cm². Pressure was 1 Torr. After this processing, contact angles of both the insulating medium layer 5 and the pixel electrode could be about 20 degrees. A polymer film comprised of PEDOT as a hole transport layer 2 was formed thereon by a spin coat method. Further, an organic light emitting layer 1 was printed by a relief printing method on a pixel electrode 3 between insulating medium layers 5 by using an organic light emitting ink in which an organic light emitting material comprising polyphenylene vinylene derivative was dissolved in toluene, wherein the concentration of a polyphenylene vinylene derivative was 1% of the ink. In this case, an anilox roll of 150 lines/inch and a photosensitive resin printing plate which was developable by water were used. A film thickness of an organic light emitting layer after printing and drying was 80 nm. In addition, after drying, a shape of cross-section was observed. As illustrated in FIG. 3, a distance between an upper surface of a pixel electrode and an upper surface of a light emitting layer increased from a part of an surface of a light emitting layer directly above a border between an insulating medium layer 5 and a pixel electrode 3 toward an insulating medium layer. The ratio of a distance between an upper surface of a pixel electrode and an upper surface of a light emitting layer directly above a border between an insulating medium layer 5 and a pixel electrode 3 to a distance between an upper surface of a pixel electrode and an upper surface of a light emitting layer at a position where a surface of a light emitting layer is connected with an insulating medium layer 5 was 1:5. As illustrated in FIG. 3, a length of left arrow was a distance between an upper surface of a pixel electrode and an upper surface of a light emitting layer directly above a border between an insulating medium layer 5 and a pixel electrode 3. Further, a length of right arrow was a distance between an upper surface of a pixel electrode and an upper surface of a light emitting layer at a position where a surface of a light emitting layer is connected with an insulating medium layer 5.

An angle between a side surface of an insulating medium layer 5 and a surface of an organic light emitting layer 1 was 4.5 degrees.

Thereupon, a line-shaped counter electrode 6 comprised of Al and Ca was formed. The counter electrode was perpendicular to the line-shaped pixel electrode 3. The counter electrode of 200 nm thickness was formed using a mask by vacuum evaporation of resistance heating mode. Glass cap 7 and adhesive 8 were used, and the organic EL device assembly was sealed last to protect the organic EL device assembly from external oxygen and moisture. An organic EL display was manufactured in this way. A fringe of a display part of the organic EL display was provided with fetch electrodes of an anode side and a cathode side. (the fetch electrodes were not illustrated in figures.) In a state where the fetch electrodes were connected to a power source, lightning of the EL display was checked. A display failure due to disconnection of a counter electrode (a cathode) was checked. As a result, display was good without a display failure due to a disconnection or a locally high resistance. In addition, when a cross-section shape was observed, the thinnest part of the electrode was about 180 nm. That is, a good counter electrode 6 (a cathode) was obtained.

### EXAMPLE 2

ITO thin film was formed by sputter method on a glass substrate 4 of which diagonal was 1.8 inches. Patterning of ITO thin film was performed by photolithography method and etching using an acid solution. Pixel electrodes 3 were formed in this way.

Line pattern of pixel electrodes 3 is described below. Line width was 136 μm. Space width was 30 μm. There were 192 lines on a glass substrate of 32 mm square.

Next, an insulating medium layer 5 was formed by processes described below. A photosensitive resist (product name “OFPR-800” (viscosity 500 cp): a product of TOKYO OHKA KOGYO Co., Ltd.) was applied to a glass substrate 4 with a pixel electrode 3 by a spin coat of 1200 rpm. After pre-baking at 110 degrees Celsius, exposure using a photo mask and development were performed. Further, after post-baking at 240 degrees Celsius, an insulating medium layer 5 was formed. At the above-mentioned conditions, an insulating medium layer 5 having a height of 5 μm was obtained.

Here, an angle between the insulating medium layer 5 and the pixel electrode 3 was 78.5 degrees. That is, the insulating medium layer had a taper shape.

Next, a substrate 1 with pixel electrode 3 and the insulating medium layer 5 was processed by oxygen plasma for 1.5 minutes. The conditions of the oxygen plasma processing are described below. Flow rate of oxygen gas was 500 sccm. Power was 1.0 W/cm². Pressure was 1 Torr. After this processing, contact angles of both the insulating medium layer 5 and the pixel electrode could be about 20 degrees. A polymer film comprised of PEDOT as a hole transport layer 2 was formed thereon by a spin coat method. Further, an organic light emitting layer 1 was printed by a relief printing method on a pixel electrode 3 between insulating medium layers 5 by using an organic light emitting ink in which an organic light emitting material comprising polyphenylene vinylene derivative was dissolved in toluene, wherein the concentration of a polyphenylene vinylene derivative was 1% of the ink. In this case, an anilox roll of 150 lines/inch and a photosensitive resin printing plate which was developable by water were used. A film thickness of an organic light emitting layer after printing and drying was 80 nm. In addition, after drying, a shape of cross-section was observed. As illustrated in FIG. 3, a distance between an upper surface of a pixel electrode and an upper surface of a light emitting layer increased from a part of an surface of a light emitting layer directly above a border between an insulating medium layer 5 and a pixel electrode 3 toward an insulating medium layer. The ratio of a distance between an upper surface of a pixel electrode and an upper surface of a light emitting layer directly above a border between an insulating medium layer 5 and a pixel electrode 3 to a distance between an upper surface of a pixel electrode and an upper surface of a light emitting layer at a position where a surface of a light emitting layer is connected with an insulating medium layer 5 was 1:4.

An angle between a side surface of an insulating medium layer 5 and a surface of an organic light emitting layer 1 was 2.9 degrees.

Thereupon, a line-shaped counter electrode 6 comprised of Al and Ca was formed. The counter electrode was perpendicular to the line-shaped pixel electrode 3. The counter electrode of 200 nm thickness was formed using a mask by vacuum evaporation of resistance heating mode. Glass cap 7 and adhesive 8 were used, and the organic EL device assembly was sealed last to protect the organic EL device assembly from external oxygen and moisture. An organic EL display was manufactured in this way. A fringe of a display part of the organic EL display was provided with fetch electrodes of an anode side and a cathode side. (the fetch electrodes were not illustrated in figures.) In a state where the fetch electrodes were connected to a power source, lightning of the EL display was checked. A display failure due to disconnection of a counter electrode (a cathode) was checked. As a result, display was good without a display failure due to a disconnection or a locally high resistance. In addition, when a cross-section shape was observed, the thinnest part of the electrode was about 180 nm. That is, a good counter electrode 6 (a cathode) was obtained.

What is claimed is:

1. An organic EL display, comprising:
a transparent substrate;
a plurality of pixel electrodes formed on the transparent substrate;
a plurality of insulating medium layers of 100 nm thickness or more sectioning the plurality of pixel electrodes;
a plurality of hole transport layers formed on the plurality of pixel electrodes;
a plurality of organic light emitting layers formed on the plurality of hole transport layers, an angle between a side surface of an insulating medium layer and a surface of a hole transport layer or an organic light emitting layer being 30 degrees or less; and
a counter electrode formed on the plurality of organic light emitting layers.

2. The organic EL display according to claim 1,
wherein the insulating medium layers are any one of an inorganic nitride film, an inorganic oxide film and an inorganic fluoride film.

3. The organic EL display according to claim 1,
wherein distance between a surface of a pixel electrode and a surface of a organic light emitting layer increases toward an insulating medium layer from a center of the surface of the pixel electrode.

4. The organic EL display according to claim 1,
wherein the side surface of the insulating medium layers slope.

5. A method for manufacturing an organic EL display including a pixel electrode, a counter electrode, a hole transport layer and an organic light emitting layer, comprising:
forming a plurality of pixel electrodes on a transparent substrate;
forming a plurality of insulating medium layers having a height of 100 nm or more over than surfaces of the plurality of pixel electrodes, the layers sectioning the pixel electrodes; and
forming the hole transport layer or the organic light emitting layer by a wet process using a thin film material solution, a contact angle between a side surface of an insulating medium layer and the thin film material solution being 30 degrees or less.

6. The method for manufacturing the organic EL display according to claim 5, wherein the organic light emitting layer is formed by a relief printing method.

7. The method for manufacturing the organic EL display according to claim 5, wherein an insulating medium layer is any one of an inorganic nitride film, an inorganic oxide film and an inorganic fluoride film.

8. An organic EL display, comprising:
a substrate;
a plurality of pixel electrodes formed on the substrate;
a plurality of insulating medium layers of 100 nm thickness or more sectioning the plurality of pixel electrodes;
a plurality of hole transport layers formed on the plurality of pixel electrodes;
a plurality of organic light emitting layers formed on the plurality of hole transport layers, an angle between a side surface of an insulating medium layer and a surface of an hole transport layer or an organic light emitting layer being 30 degrees or less; and
a counter electrode formed on the plurality of organic light emitting layers.
